(19) United States
(12) Patent Application Publication
(10) Pub. No.: US 2006/0202045 A1
(43) Pub. Date: Sep. 14, 2006

(54) Low-noise cooling method and apparatus for computer host

(76) Inventor: Teng-Chieh Liu, Sindian City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/078,431

(22) Filed: Mar. 14, 2005

(51) Int. Cl. F24F 7/00; F25D 23/12; H05K 7/20

(52) U.S. Cl. 236/49.3; 62/259.2

(57) ABSTRACT

This invention relates to a low-noise cooling method and device for a computer host. In the preferred embodiment, an electric gate and a fan are provided for the computer host. In addition, the invention includes a control circuit for controlling open/close states of the electric gate and rotation speeds of the fan according to an interior temperature of the computer host. When the interior temperature of the computer host decreases, the noise generated by the fan decreases due to a slightly open state of the electric gate and a reduced rotation speed of the fan. Therefore, the power consumption of the computer host and the noise of the fan are decreased.

### BACKGROUND OF THE INVENTION

(1) Field of the Invention

The invention relates to cooling technology for computer hosts, and more particularly to a low-noise cooling method and apparatus for a computer host.

(2) Description of the Prior Art

Traditional computer hosts use the fan arranged on the back panel to dissipate the heat generated during operation. Recently, it is often seen that another fan installed on the front panel of a computer host because the power consumption of current CPU tremendously increases.

However, inevitably, the noise generated by the fan, no matter on the back panel fan or the front panel fan, is annoying and badly affects the user if there is no proper isolation for the noise. Moreover, the noise will influence moods to the user and damage the hearing of the user.

### SUMMARY OF THE INVENTION

Accordingly, it is one object of the present invention to provide a low-noise cooling method and apparatus for a computer host so as to suppress noise generated by a fan in the computer host and thus reduce the effect of the noise on the user.

The present invention provides a fan and an electric gate for a computer host. The electric gate opens and closes in proportion to changes of the interior temperature of the computer host or rotation speeds of the fan. In this way, the noise generated by the fan is reduced by the electrical gate, which has a slightly open state when the interior temperature of the computer host or the rotation speed of the fan decreases.

In addition, the rotation speeds of the fan change in proportion to the changes of the interior temperature. As a result, when the interior temperature of the computer host reduces, the noise generated by the fan is reduced because the open state of the electrical gate becomes smaller and the rotation speed of the fan decreases.

Obviously, once the noise generated by the fan is decreased by the reduced interior temperature of the computer host or the reduced rotation speed of the fan, the probability of the noise affecting to the user is also reduced. Therefore, the power consumption of the fan is decreased due to the reduced rotation speed of the fan.

### BRIEF DESCRIPTION OF THE DRAWINGS

The present invention will now be specified with reference to its preferred embodiment illustrated in the drawings, in which

FIG. 1 shows a schematic view depicting the preferred embodiment of the present invention;

FIG. 2 through FIG. 4 show the operation of the referred embodiment of the present invention; and

FIG. 5 shows a schematic block diagram depicting the control circuit of the preferred embodiment of the present invention.

### DESCRIPTION OF THE PREFERRED EMBODIMENT

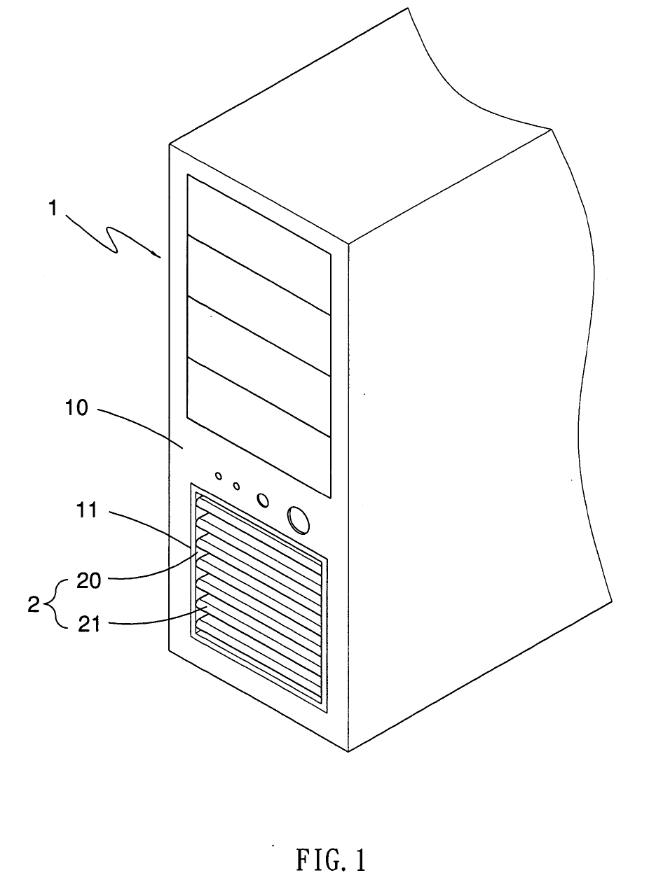

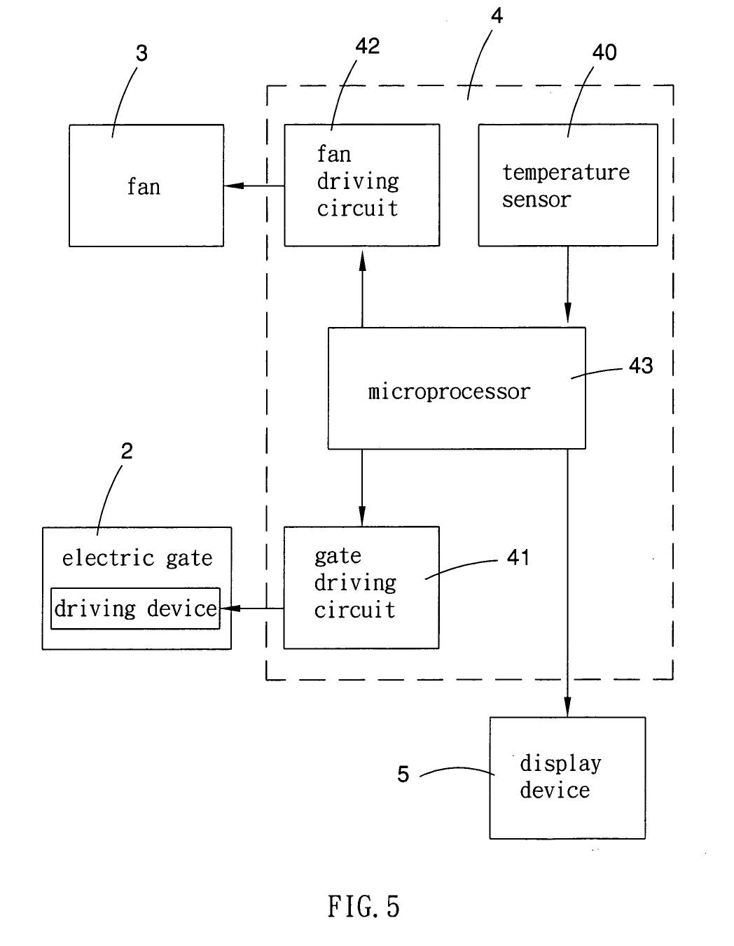

FIG. 1 shows a schematic view depicting of the present cooling apparatus. In FIG. 1, a vent 11 is formed on a front panel 10 of a computer host 1. The vent 11 includes an electric gate 2 installed therein. The electric gate 2 further includes a frame 20 mounted to the vent 11 and a plurality of blades 21 which are parallel to each other and rotatably connected to the frame 20. Two ends of each blade 21 are respectively connected to one side and the opposite side of the frame. The electric gate 2 further includes a driving device (shown in FIG. 5) having a motor and a transmission system (not shown). Via the transmission system, the motor drives the blades 21 to rotate synchronously.

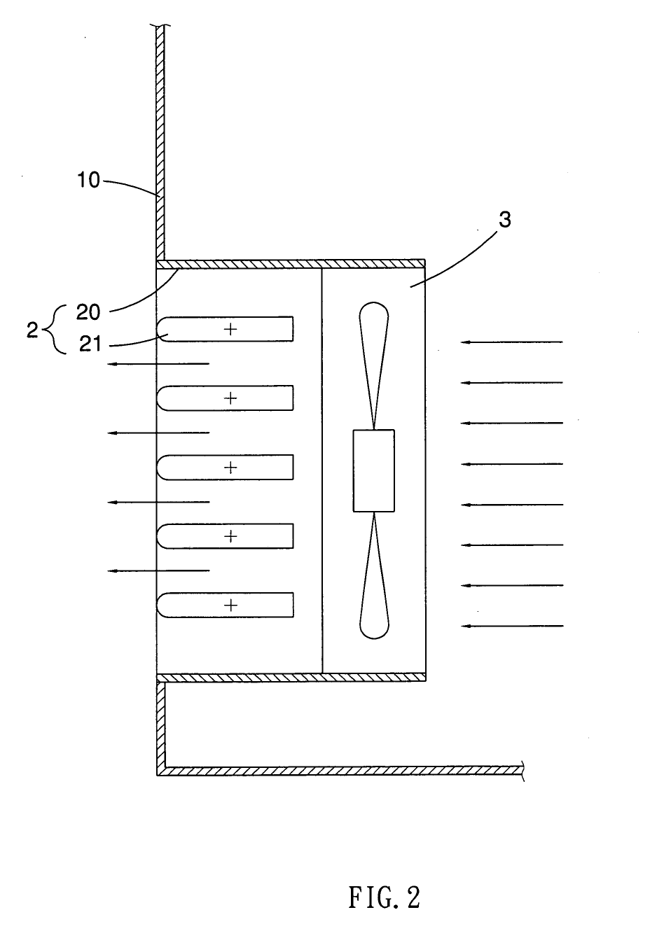

Referring to FIG. 2, the computer host 1 includes a fan 3 installed therein. The fan 3 is provided for circulating airflow of the interior of the computer host 1 to the exterior of the computer host 1 when the electric gate 2 is opened. As shown in FIG. 2, the blades 21 rotate synchronously to horizontal positions, which means that the electric gate 2 is fully opened. In other words, the electric gate 2 is in a fully open state, which means the blades 21 of the electric gate 2 rotate synchronously to an angle of 90 degree clockwise.

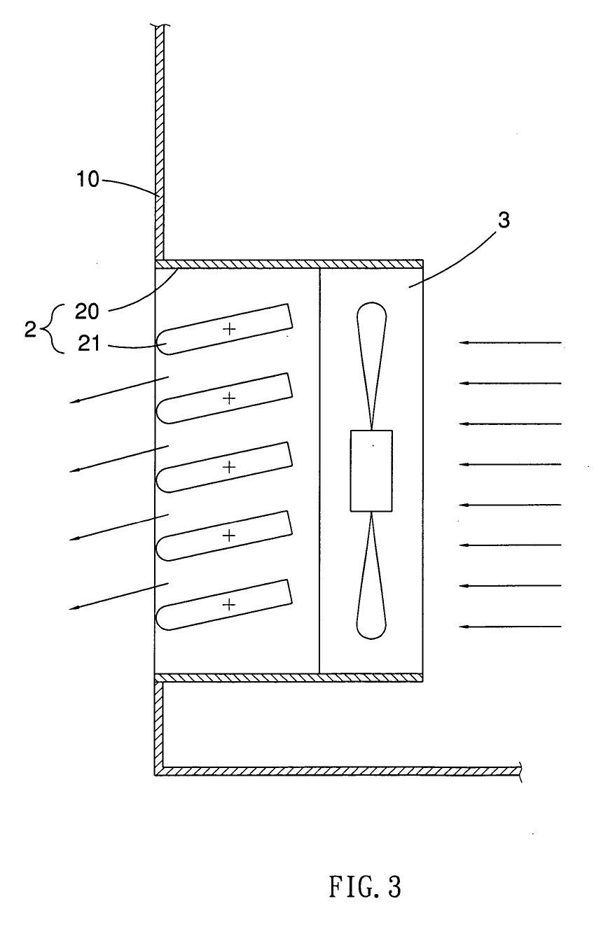

FIG. 3 shows the blades 21 of the electric gate 2 rotate synchronously to an angle of 45 degree, which means that the electric gate 2 is in a half open state.

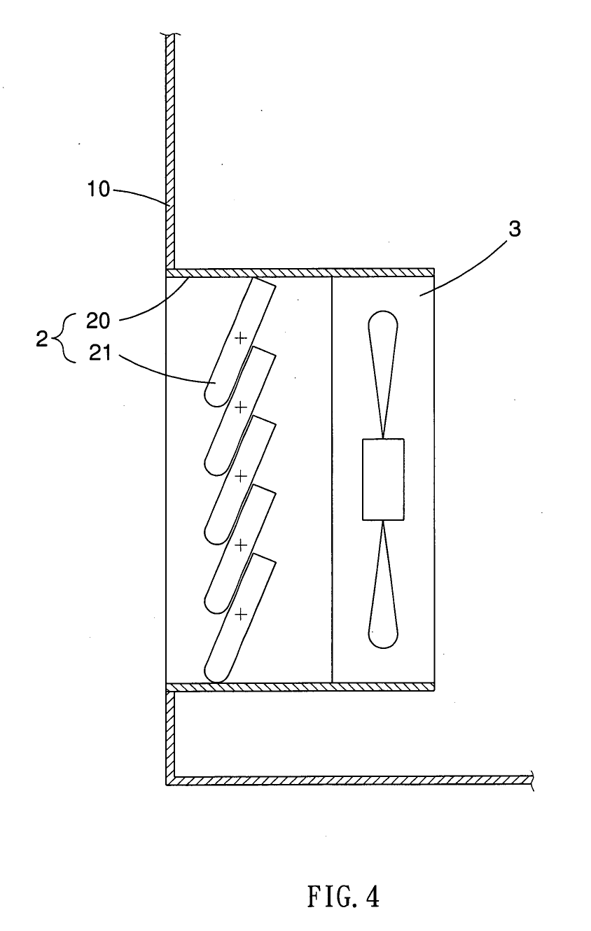

FIG. 4 shows the blades 21 of the electric gate 2 partially overlap with each other, which means that the electric gate 2 is in a fully close state. That is, the rotation angle of the blades 21 is in an angle of zero degree. At the same time, the fan 3 is motionless.

From the above description, it is understood that the state of the electric gate 2 can be opened or tilted from a zero degree (fully close state) to a 90 degree (fully open state). In addition, the smaller the tilted angle of the electric gate 2, the higher the quietness. Therefore, the present invention uses the angle-variable electric gate 2 to suppress the noise generated by the fan 3. Meanwhile, the rotation speed of the fan 3 is reduced in response to the reduced temperature in the interior of the host 1. As a result, the power consumption of the fan 3 is also reduced and much higher electricity is thus saved.

FIG. 5 shows a schematic view depicting the block diagram of a control circuit 4 installed in the interior of the computer host 1. The control circuit 4 includes a temperature sensor 40, a gate driving circuit 41, a fan driving circuit 42, and a microprocessor 43. The temperature sensor 40 is provided for sensing the interior temperature of the computer host 1 and the gate driving circuit 41 is provided for driving the electric gate 2 to rotate. The fan driving circuit 42 is provided for driving the fan 3. In addition, the microprocessor 43 is provided for controlling the open/close state of the electric gate 2 via the gate driving circuit 41 and the rotation speed of the fan 3 via the fan driving circuit 42 according to a sensed condition sensed by the temperature sensor 40 and a pre-determined table.

In particular, the pre-determined table defines the corresponding relationships among a plurality of temperature ranges of the computer host 1, a plurality of open/close states of the electric gate 2 and a plurality of rotation speeds of the fan 3. One embodiment of the table is shown as follows.

| Temperature Range | Open/close State (angle) | Rotation Speed |
|---|---|---|
| Above 40° C. | Fully Open (90°) | Full Speed |
| 35° C.˜40° C. | Half Open (45°) | Half Speed |
| 30° C.˜35° C. | Quarter Open (15°) | Quarter Speed |
| below 30° C. | Fully close (0°) | 0 |

Therefore, after acquiring the internal temperature of the computer host 1, the microprocessor 43 is able to locate the corresponding angle and the corresponding rotation based on the pre-determined table so as to drive the electric gate 2 rotating to the desired angle and the fan 3 rotating at the desired rotation speed. For example, when the interior temperature of the computer host 1 sensed by the temperature sensor 40 is 38-centigrade degree, the microprocessor 43 drives the electric gate 2 rotating to the angle 45 degree via the gate driving circuit 41, according to the above table. Also as shown in FIG. 3, the microprocessor 43 simultaneously drives the fan 3 rotating at the rotation speed of 1800 rpm via the fan driving circuit 42. Furthermore, the control circuit 4 of the present invention could further comprise a detecting circuit (not shown) provided for detecting rotation speeds of the fan 3.

In the above embodiment, although the open/close states of the electric gate 2 is varied according to the interior temperature of the computer host 1, it will be apparent to those skilled in the art to contemplate that the open/close states of the electric gate 2 could be varied according to the rotation speeds of the fan 3.

In addition, FIG. 5 further shows the present invention comprises a display device 5, mounted to the front panel 10 of the computer host 1 and electrically connected to the microprocessor 43 of the control circuit 4 for displaying the interior temperature of the computer host 1. The display device 5 can be further applied to display the operation conditions of the electric gate 2 and the fan 3, such as the open/close state of the electric gate 2, the current rotation speed of the fan 3 and so on.

While the preferred embodiments of the present invention have been set forth for the purpose of disclosure, modifications of the disclosed embodiments of the present invention as well as other embodiments thereof may occur to those skilled in the art. Accordingly, the appended claims are intended to cover all embodiments which do not depart from the spirit and scope of the present invention.

I claim:

1. A low-noise cooling method for a computer host, comprising the steps of:
providing an electric gate and a fan for mounting to the computer host;
defining a plurality of temperature ranges for the computer host and a plurality of open/close states for the electric gate, each temperature range corresponding to one open/close state;
acquiring an interior temperature of the computer host;
locating the temperature range corresponding to the interior temperature of the computer host; and
driving the electric gate to have the open/close state of the electric gate corresponding to the temperature range.

2. The method according to claim 1, wherein the step of defining a plurality of temperature ranges for the computer host and a plurality of open/close states for the electric gate further comprises:
defining a plurality of rotation speeds for the fan, each temperature range corresponding to one open/close state of the electric gate and one rotation speed of the fan; and
wherein the step of driving the electric gate further comprises driving the fan to have the rotation speed of the fan corresponding to the temperature range.

3. A low-noise cooling method for a computer host which includes a fan, the method comprising the steps of:
providing an electric gate for mounting to the computer host;
defining a plurality of rotation speeds for the fan and a plurality of open/close states for the electric gate, each rotation speed corresponding to one open/close state;
acquiring an actual rotation speed of the fan;
locating the rotation speed of the fan corresponding to the actual rotation speed of the fan; and
driving the electric gate to have the open/close state of the electric gate corresponding to the rotation speed of the fan.

4. A low-noise apparatus for a computer host comprising:
an electric gate, mounted to the computer host;
a fan, installed in an interior of the computer host and provided for circulating airflow of the interior of the computer host to the exterior of the computer host when the electric gate is opened; and
a control circuit, installed in the interior of the computer host and provided for controlling open/close states of the electric gate.

5. The apparatus according to claim 4, wherein the control circuit further comprises:
a temperature sensor, provided for sensing an interior temperature of the computer host;
a gate driving circuit, provided for driving the electric gate; and
a microprocessor, provided for controlling the gate driving circuit corresponding to a sensed condition sensed by the temperature sensor.

6. The apparatus according to claim 4, wherein the control circuit further comprises:
a temperature sensor, provided for sensing an interior temperature of the computer host;
a gate driving circuit, provided for driving the electric gate;
a fan driving circuit, provided for driving the fan; and
a microprocessor, provided for controlling the gate driving circuit and the fan driving circuit corresponding to a sensed condition sensed by the temperature sensor.

7. The apparatus according to claim 4, wherein the control circuit further comprises:
a detecting circuit, provided for detecting rotation speeds of the fan.

8. The apparatus according to claim 4, wherein the electric gate further comprises:
a frame, mounted to a vent of the computer host;
a plurality of blades, being parallel to each other and being rotatably connected to the frame, wherein two ends of each blade are respectively connected to one side and the opposite side of the frame; and
a driving device, including a motor and a transmission system, the motor driving the blades to rotate synchronously via the transmission system.

9. The apparatus according to claim 5, wherein the electric gate further comprises:
a frame, mounted to a vent of the computer host;
a plurality of blades, being parallel to each other and being rotatably connected to the frame, wherein two ends of each blade are respectively connected to one side and the opposite side of the frame; and
a driving device, including a motor and a transmission system, the motor driving the blades to rotate synchronously via the transmission system.

10. The apparatus according to claim 6, wherein the electric gate further comprises:
a frame, mounted to a vent of the computer host;
a plurality of blades, being parallel to each other and being rotatably connected to the frame, wherein two ends of each blade are respectively connected to one side and the opposite side of the frame; and
a driving device, including a motor and a transmission system, the motor driving the blades to rotate synchronously via the transmission system.

11. The apparatus according to claim 5, further comprising:
a display device, electrically connected to the microprocessor and provided for displaying the interior temperature of the computer host.

12. The apparatus according to claim 6, further comprising:
a display device, electrically connected to the microprocessor and provided for displaying the interior temperature of the computer host.

13. The apparatus according to claim 9, further comprising:
a display device, electrically connected to the microprocessor and provided for displaying the interior temperature of the computer host.

14. The apparatus according to claim 10, further comprising:
a display device, electrically connected to the microprocessor and provided for displaying the interior temperature of the computer host.
